(19) United States
(12) Patent Application Publication
(10) Pub. No.: US 2025/0069532 A1
(43) Pub. Date: Feb. 27, 2025

(54) TOUCH INTEGRATED CIRCUIT INSPECTION DEVICE

(71) Applicant: SAMSUNG DISPLAY CO., LTD., YONGIN-SI (KR)

(72) Inventors: KYUSHIK SHIN, Yongin-si (KR); JUN-YOUNG KO, Yongin-si (KR); TAEHYEON YANG, Yongin-si (KR); JAEHYUNG JO, Yongin-si (KR)

(21) Appl. No.: 18/762,952

(22) Filed: Jul. 3, 2024

(30) Foreign Application Priority Data
Aug. 25, 2023 (KR) 10-2023-0111712

(51) Int. Cl. G09G 3/00; G06F 3/044

(52) U.S. Cl. CPC G09G 3/006; G06F 3/0446; G06F 3/0448; G09G 2330/12

(57) ABSTRACT

A touch integrated circuit (IC) inspection device includes: an inspection board electrically connected to a touch IC; and an inspection circuit that receives an inspection result from the touch IC, wherein the inspection board includes: a plurality of first electrodes, each of which extends in a first direction and which are spaced apart from one another in a second direction that intersects the first direction; and a plurality of second electrodes, each of which extends in the second direction and which are spaced apart from one another in the first direction, and wherein a number of the plurality of first electrodes is a same as a number of the plurality of second electrodes.

### CROSS-REFERENCE TO RELATED APPLICATION

This application claims priority under 35 U.S.C. § 119 to Korean Patent Application No. 10-2023-0111712 filed on Aug. 25, 2023, in the Korean Intellectual Property Office, the disclosure of which is incorporated by reference herein in its entirety.

### TECHNICAL FIELD

Embodiments of the present invention relate to a touch integrated circuit (IC) inspection device for detecting defects in a touch IC.

### DISCUSSION OF THE RELATED ART

There are various display modules that are currently under development and that are used in a multi-media device such as a television, a mobile phone, a tablet computer, a navigation system, or a game console. Generally, each of the display modules includes pixels and drive circuits. Moreover, each of the display modules is equipped with an input sensor that recognizes an input from a user such as a touch input.

### SUMMARY

According to an embodiment of the present invention, a touch integrated circuit (IC) inspection device includes: an inspection board electrically connected to a touch IC; and an inspection circuit that receives an inspection result from the touch IC, wherein the inspection board includes: a plurality of first electrodes, each of which extends in a first direction and which are spaced apart from one another in a second direction that intersects the first direction; and a plurality of second electrodes, each of which extends in the second direction and which are spaced apart from one another in the first direction, and wherein a number of the plurality of first electrodes is a same as a number of the plurality of second electrodes.

In an embodiment of the present invention, each of the plurality of first electrodes and the plurality of second electrodes have a polygonal shape.

In an embodiment of the present invention, each of the plurality of first electrodes and the plurality of second electrodes have a rectangular shape.

In an embodiment of the present invention, a first part of each of the plurality of second electrodes and the plurality of first electrodes are disposed on a same layer.

In an embodiment of the present invention, the inspection board further includes: a first resistor electrically connected to one end of each of the plurality of first electrodes; and a first capacitor connected between the first resistor and a ground electrode.

In an embodiment of the present invention, the inspection board further includes: a second resistor electrically connected to one end of each of the plurality of second electrodes; and a second capacitor connected between the second resistor and the ground electrode.

In an embodiment of the present invention, the first resistor is a variable resistor, and wherein the first capacitor is a variable capacitor.

In an embodiment of the present invention, the ground electrode is disposed on a same layer as a second part of each of the plurality of second electrodes.

In an embodiment of the present invention, the inspection board further includes: a first ground layer disposed on the plurality of first electrodes and the plurality of second electrodes; and a second ground layer disposed under the plurality of first electrodes and the plurality of second electrodes.

In an embodiment of the present invention, a plurality of first slits, each of which extends in the second direction and which are spaced apart from one another in the first direction, are disposed on the first ground layer, and wherein the plurality of first slits overlap the plurality of first electrodes and the plurality of second electrodes.

In an embodiment of the present invention, self-capacitance of each of the plurality of first electrodes is controlled by a width, in a first direction, of each of the plurality of first slits.

In an embodiment of the present invention, a plurality of second slits, each of which extends in the first direction and which are spaced apart from one another in the second direction, are disposed on the second ground layer, and wherein the plurality of second slits overlap the plurality of first electrodes and the plurality of second electrodes.

In an embodiment of the present invention, a plurality of openings, each of which has a polygonal shape and which are arranged in the first direction and the second direction, are disposed on the first ground layer, and wherein the plurality of openings overlap the plurality of first electrodes and the plurality of second electrodes.

According to an embodiment of the present invention, a touch integrated circuit (IC) inspection device includes: an inspection board electrically connected to a touch IC, wherein the inspection board includes: a plurality of first electrodes, each of which extends in a first direction and which are spaced apart from one another in a second direction that intersects the first direction; a plurality of second electrodes, each of which extends in the second direction and which are spaced apart from one another in the first direction; a first resistor electrically connected to one end of each of the plurality of first electrodes; and a first capacitor connected between the first resistor and a ground electrode.

In an embodiment of the present invention, the first resistor is a variable resistor, and wherein the first capacitor is a variable capacitor.

In an embodiment of the present invention, the inspection board further includes: a second resistor electrically connected to one end of each of the plurality of second electrodes; and a second capacitor connected between the second resistor and the ground electrode.

In an embodiment of the present invention, a first part of each of the plurality of second electrodes and the plurality of first electrodes are disposed on a same layer.

In an embodiment of the present invention, the ground electrode is disposed on a same layer as a second part of each of the plurality of second electrodes.

In an embodiment of the present invention, at least one of the plurality of first electrodes or the plurality of second electrodes have a diamond shape.

In an embodiment of the present invention, at least one of the plurality of first electrodes or the plurality of second electrodes have a rectangular shape.

### BRIEF DESCRIPTION OF THE FIGURES

The above and other features of the present invention will become apparent by describing in detail embodiments thereof with reference to the accompanying drawings, in which:

FIG. 1 is a perspective view of a display device, according to an embodiment of the present invention.

FIG. 2 is an exploded perspective view of a display device, according to an embodiment of the present invention.

FIG. 3 is a block diagram illustrating an operation of a display device, according to an embodiment of the present invention.

FIG. 4A is a cross-sectional view of a display device, according to an embodiment of the present invention.

FIG. 4B is a cross-sectional view of a display device, according to an embodiment of the present invention.

FIG. 5 is a cross-sectional view of a display device taken along line I-I′ of FIG. 1, according to an embodiment of the present invention.

FIG. 6 is a block diagram showing a touch IC inspection device, according to an embodiment of the present invention.

FIG. 7 is a conceptual diagram showing an inspection board, according to an embodiment of the present invention.

FIG. 8 is a cross-sectional view of an inspection board taken along I-I′ of FIG. 7, according to an embodiment of the present invention.

FIG. 9 is a cross-sectional view of an inspection board obtained by cutting a portion corresponding to area AA′ of FIG. 7, according to an embodiment of the present invention.

FIG. 10 is a plan view illustrating an inspection board, according to an embodiment of the present invention.

FIG. 11 is a plan view illustrating an inspection board, according to an embodiment of the present invention.

FIG. 12 is a cross-sectional view illustrating an inspection board, according to an embodiment of the present invention.

FIG. 13 is a plan view illustrating a first ground layer, according to an embodiment of the present invention.

FIG. 14 is a plan view illustrating a second ground layer, according to an embodiment of the present invention.

FIG. 15 is a plan view illustrating an inspection board, according to an embodiment of the present invention.

FIG. 16 illustrates an inspection result of measuring capacitance for each channel, according to an embodiment of the present invention.

### DETAILED DESCRIPTION OF EMBODIMENTS

In the specification, the expression that a first component (or region, layer, part, portion, etc.) is “on”, “connected with”, or “coupled with” a second component means that the first component is directly on, connected with, or coupled with the second component or that a third component is interposed therebetween.

The same reference numerals refer to the same components throughout the specification. In addition, various thicknesses, lengths, and angles are shown and while the arrangement shown does indeed represent an embodiment of the present invention, it is to be understood that modifications of the various thicknesses, lengths, and angles may be possible within the spirit and scope of the present disclosure and the present disclosure is not necessarily limited to the particular thicknesses, lengths, and angles shown. The term “and/or” includes one or more combinations in each of which associated elements are defined.

Although the terms “first”, “second”, etc. may be used to describe various components, the components should not be construed as being limited by the terms. The terms are only used to distinguish one component from another component. For example, without departing from the scope and spirit of the present invention, a first component may be referred to as a second component, and similarly, the second component may be referred to as the first component without departing from the spirit and scope of the present invention. As used herein, the terms of a singular form may include a plural form unless the context clearly indicates otherwise.

Also, terms such as “below,” “lower,” “above,” and “upper” may be used to describe the relationships of the components illustrated in the drawings. These terms are used as a spatially relative concept and are described based on the directions indicated in the drawings. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Hereinafter, embodiments of the present invention will be described with reference to accompanying drawings.

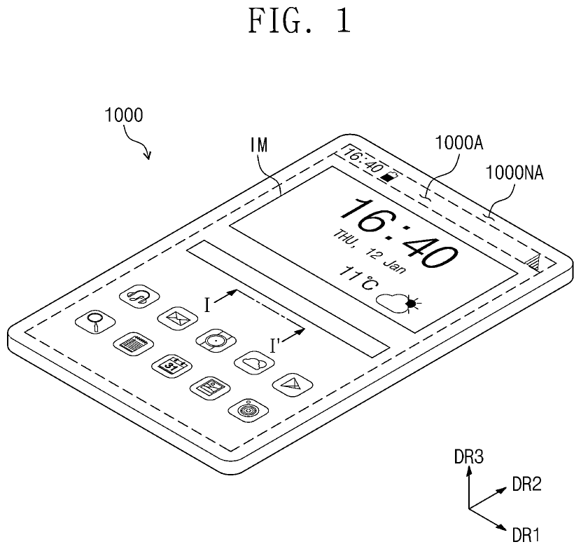

FIG. 1 is a perspective view of a display device, according to an embodiment of the present invention.

Referring to FIG. 1, in this specification, a display device 1000 that may be applied to a mobile phone terminal is illustrated; however, this is merely an example and the present invention is not limited thereto. Although not illustrated in drawings, the mobile phone terminal may be implemented by positioning electronic modules, a camera module, a power module, and the like, which are mounted on a main board, in a bracket or a case together with the display device 1000. However, this is an example, and the display device 1000 according to an embodiment of the present invention is not limited thereto. For example, the display device 1000 may be applied to a small and medium-sized display device, such as a tablet PC, a vehicle navigation system, a game console, a smart watch, or the like as well as a large-sized display device, such as a television, a monitor, or the like.

An active area 1000A and a peripheral area 1000NA may be defined in the display device 1000. The display device 1000 may display an image IM through the active area 1000A. Icon images are illustrated as an example of the image IM. The active area 1000A may be parallel to a plane defined by a first direction DR1 and a second direction DR2. The normal direction (i.e., the thickness direction of the display device 1000) of the active area 1000A may be defined as a third direction DR3. In the specification, “when viewed from above a plane or on a plane” may mean “when viewed in the third direction DR3”. A front surface (or, e.g., an upper surface) and a back surface (or, e.g., a lower surface) of each layer or unit described later may be divided by the third direction DR3.

The peripheral area 1000NA may be adjacent to the active area 1000A. The peripheral area 1000NA may be an area in which the image IM is not displayed. However, the present invention is not limited thereto, and the peripheral area 1000NA may be adjacent to one side of the active area 1000A or may be omitted.

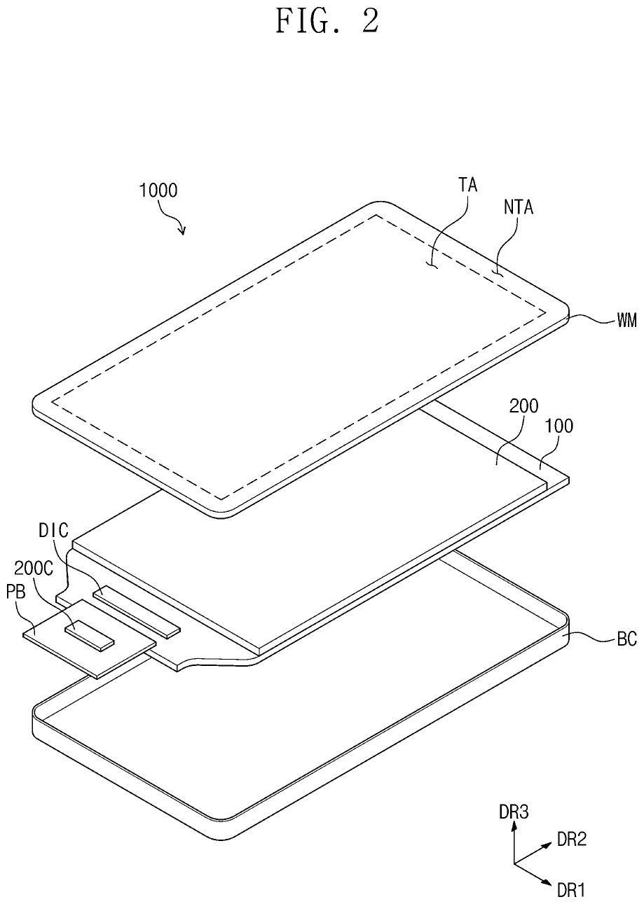

FIG. 2 is an exploded perspective view of a display device, according to an embodiment of the present invention.

Referring to FIG. 2, the display device 1000 may include a window WM, a display layer 100, a sensor layer 200, a data driver DIC, a circuit board PB, a touch IC 200C, and a receiving member BC.

The window WM may be disposed on the sensor layer 200. The window WM may transmit an image provided from the display layer 100 to the outside. The window WM may include a transmission area TA and a non-transmission area NTA. The transmission area TA may overlap the display area 1000A (see FIG. 1) of the display device 1000. The transmission area TA may have a shape corresponding to the display area 1000A (see FIG. 1). The image IM (see FIG. 1) displayed on the display area 1000A (see FIG. 1) of the display device 1000 may be visible from the outside through the transmission area TA of the window WM.

The non-transmission area NTA may overlap the peripheral area 1000NA (see FIG. 1) of the display device 1000. The non-transmission area NTA may have a shape corresponding to the peripheral area 1000NA (see FIG. 1). The non-transmission area NTA may be an area having lower light transmittance than that of the transmission area TA. However, the window WM according to an embodiment of the present invention is not limited thereto, and the non-transmission area NTA may be omitted.

The window WM may be formed of, for example, glass, sapphire, plastic, etc. Moreover, the window WM may include a single layer or a plurality of layers. The window WM may include at least one printed layer that overlaps a base layer and the non-transmission area NTA, and for example, the at least one printed layer may be disposed on the back surface of the base layer. The printed layer may have a predetermined color. For example, the printed layer may be provided in black or in a color other than black.

The display layer 100 and the sensor layer 200 may be interposed between the window WM and the receiving member BC. The sensor layer 200 may be disposed on the display layer 100. This will be described later.

The data driver DIC may be mounted on the display layer 100. The circuit board PB is disposed at one end of the display layer 100 and may be electrically connected to the display layer 100. The circuit board PB may be rigid or flexible. For example, when the circuit board PB is flexible, the circuit board PB may be provided as a flexible printed circuit board. The circuit board PB may include the touch IC 200C that controls the operation of the sensor layer 200. The touch IC 200C may be mounted on the circuit board PB in a form of an integrated chip. Moreover, the circuit board PB may further include circuits for controlling the display layer 100.

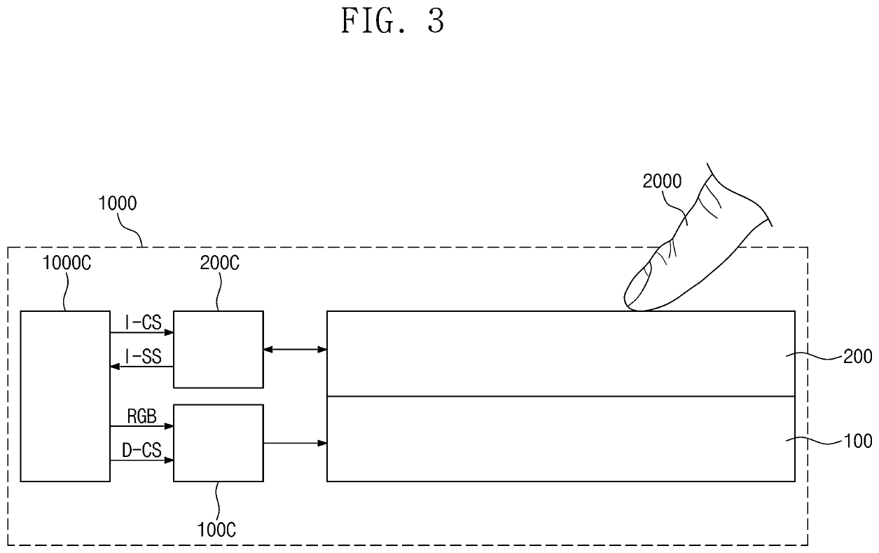

FIG. 3 is a block diagram illustrating an operation of a display device, according to an embodiment of the present invention.

Referring to FIG. 3, the display device 1000 may include the display layer 100, the sensor layer 200, a driving controller 100C, the touch IC 200C, and a main driver 1000C.

The display layer 100 may be a component that substantially generates an image. The display layer 100 may include a light emitting display layer. For example, the display layer 100 may be an organic light emitting display layer, a quantum dot display layer, a micro-LED display layer, or a nano-LED display layer. For example, the display layer 100 may be referred to as a “display panel”.

The sensor layer 200 may be disposed on the display layer 100. The sensor layer 200 may sense an external input 2000 that is applied from the outside. The external input 2000 may include any input means capable of providing a change in capacitance in the sensing layer 200. For example, the sensor layer 200 might not sense only a passive-type input means such as a user's body, but also an input by an active-type input means that provides a transfer signal. For example, the sensor layer 200 may be referred to as a “sensor”, “touch layer”, “touch panel”, “input sensing layer”, or “input sensing panel”.

The main driver 1000C may control overall operations of the display device 1000. For example, the main driver 1000C may control operations of the driving controller 100C and the touch IC 200C. The main driver 1000C may include at least one microprocessor, and the main driver 1000C may be referred to as a “host”. The main driver 1000C may further include a graphic controller.

The driving controller 100C may drive the display layer 100. The driving controller 100C may receive image data RGB and a control signal D-CS from the main driver 1000C. The control signal D-CS may include various signals. For example, the control signal D-CS may include an input vertical synchronization signal, an input horizontal synchronization signal, a main clock, and a data enable signal. The driving controller 100C may generate a scan control signal and a data control signal for controlling the driving of the display layer 100 based on the control signal D-CS.

The touch IC 200C may drive the sensor layer 200. The touch IC 200C may receive a control signal I-CS from the main driver 1000C. The control signal I-CS may include a clock signal.

The touch IC 200C may calculate coordinate information of an input based on a signal received from the sensor layer 200, and may provide the main driver 1000C with a coordinate signal I-SS having the coordinate information. The main driver 1000C executes an operation corresponding to a user input based on the coordinate signal I-SS. For example, the main driver 1000C may operate the driving controller 100C such that a new image is displayed on the display layer 100.

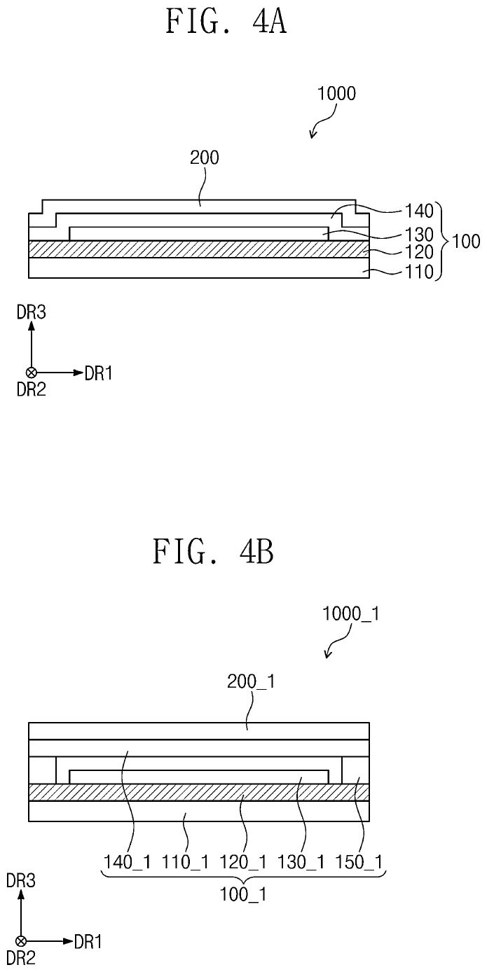

FIG. 4A is a cross-sectional view of a display device, according to an embodiment of the present invention.

Referring to FIG. 4A, the display layer 100 may include a base layer 110, a circuit layer 120, a light emitting element layer 130, and an encapsulation layer 140.

The base layer 110 may be a member that provides a base surface on which the circuit layer 120 is disposed. The base layer 110 may be, for example, a glass substrate, a metal substrate, a polymer substrate, or the like. However, an embodiment of the present invention is not limited thereto, and the base layer 110 may be an inorganic layer, an organic layer, or a composite material layer.

The base layer 110 may have a multi-layer structure. For example, the base layer 110 may include a first synthetic resin layer, a silicon oxide (SiOx) layer disposed on the first synthetic resin layer, an amorphous silicon (a-Si) layer disposed on the silicon oxide layer, and a second synthetic resin layer disposed on the amorphous silicon layer. For example, the silicon oxide layer and the amorphous silicon layer may be referred to as a “base barrier layer”.

Each of the first and second synthetic resin layers may include polyimide-based resin. In addition, each of the first and second synthetic resin layers may include at least one of acrylate-based resin, methacrylate-based resin, polyisoprene-based resin, vinyl-based resin, epoxy-based resin, urethane-based resin, cellulose-based resin, siloxane-based resin, polyamide-based resin, and/or perylene-based resin.

The circuit layer 120 may be disposed on the base layer 110. The circuit layer 120 may include, for example, an insulating layer, a semiconductor pattern, a conductive pattern, and a signal wire. The insulating layer, the semiconductor layer, and the conductive layer may be formed on the base layer 110 in a manner such as coating, evaporation, or the like. Afterward, the insulating layer, the semiconductor layer, and the conductive layer may be selectively patterned by performing a photolithography process multiple times. Afterward, the semiconductor pattern, the conductive pattern, and the signal wire included in the circuit layer 120 may be formed.

The light emitting element layer 130 may be disposed on the circuit layer 120. The light emitting element layer 130 may include a light emitting element. For example, the light emitting element layer 130 may include an organic light emitting material, a quantum dot, a quantum rod, a micro-LED, or a nano-LED.

The encapsulation layer 140 may be disposed on the light emitting element layer 130. The encapsulation layer 140 may protect the light emitting element layer 130 from foreign substances such as moisture, oxygen, and dust particles. For example, the encapsulation layer 140 may include an inorganic layer and an organic layer.

The sensor layer 200 may be disposed on the display layer 100. The sensor layer 200 may sense an external input that is applied from the outside. The external input may be a user input. The user input may include various types of external inputs such as a part of a user body, light, heat, a pen, or pressure.

The sensor layer 200 may be formed on the display layer 100 through a successive process. For example, the sensor layer 200 may be expressed as being directly disposed on the display layer 100. “Being directly disposed” may mean that the third component is not interposed between the sensor layer 200 and the display layer 100. For example, a separate adhesive member might not be interposed between the sensor layer 200 and the display layer 100. In addition, the sensor layer 200 may be coupled to the display layer 100 through an adhesive member. The adhesive member may include a common adhesive or a common sticking agent.

The display device 1000 may further include an anti-reflection layer and an optical layer, which are disposed on the sensor layer 200. The anti-reflection layer may reduce the reflectance of external light that is incident from the outside of the display device 1000. The optical layer may increase the front luminance of the display device 1000 by controlling a direction of light that is incident from the display layer 100.

FIG. 4B is a cross-sectional view of a display device, according to an embodiment of the present invention.

Referring to FIG. 4B, a display device 1000_1 may include a display layer 100_1 and a sensor layer 200_1. The display layer 100_1 may include a base substrate 110_1, a circuit layer 120_1, a light emitting element layer 130_1, an encapsulation substrate 140_1, and a coupling member 150_1.

Each of the base substrate 110_1 and the encapsulation substrate 140_1 may be, for example, a glass substrate, a metal substrate, or a polymer substrate, but the present invention is not particularly limited thereto.

The coupling member 150_1 may be interposed between the base substrate 110_1 and the encapsulation substrate 140_1. The coupling member 150_1 may couple the encapsulation substrate 140_1 to the base substrate 110_1 or the circuit layer 120_1. The coupling member 150_1 may include an inorganic material or an organic material. For example, the inorganic material may include a frit seal, and the organic material may include a photo-curable resin or a photo-plastic resin. However, the material constituting the coupling member 150_1 is not limited to the example.

The sensor layer 200_1 may be disposed on the encapsulation substrate 140_1. For example, the sensor layer 200_1 may be directly disposed on the encapsulation substrate 140_1. “Being directly disposed” may mean that the third component is not interposed between the sensor layer 200_1 and the encapsulation substrate 140_1. For example, a separate adhesive member might not be interposed between the sensor layer 200_1 and the display layer 100_1. However, an embodiment of the present invention is not limited thereto, and an adhesive layer may be interposed between the sensor layer 200_1 and the encapsulation substrate 140_1.

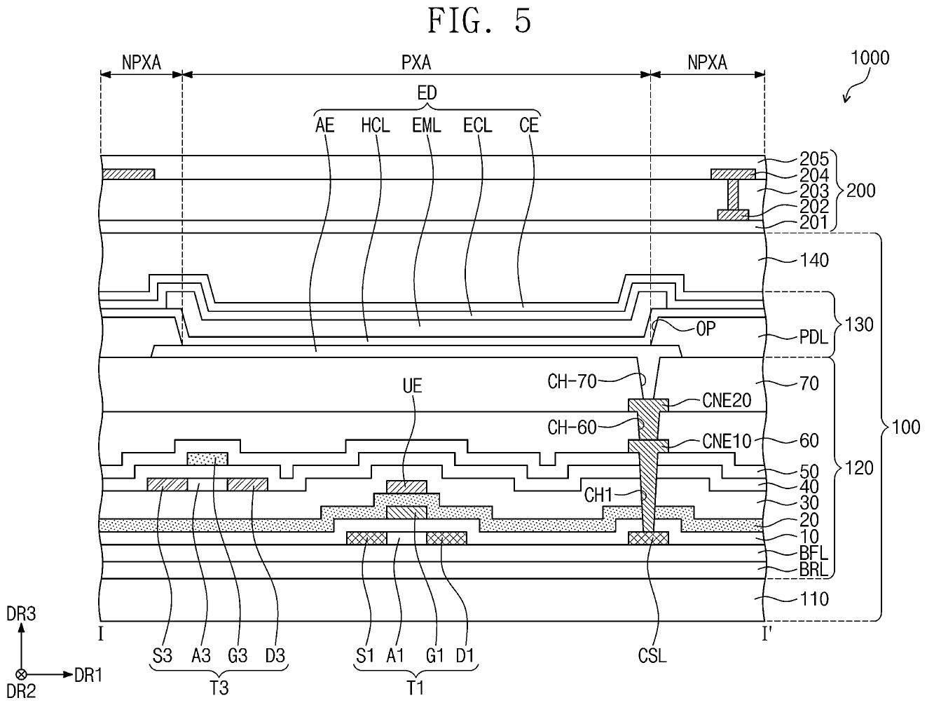

FIG. 5 is a cross-sectional view of a display device taken along line I-I′ of FIG. 1, according to an embodiment of the present invention.

Referring to FIG. 5, the display device 1000 may include the display layer 100 and the sensor layer 200 that is disposed on the display layer 100.

The display layer 100 may include the base layer 110, the circuit layer 120, the light emitting element layer 130, and the encapsulation layer 140 that are disposed on the base layer 110.

The base layer 110 may include, for example, a synthetic resin layer. The synthetic resin layer may include a thermosetting resin. For example, the synthetic resin layer may be a polyimide-based resin layer, and the material thereof is not particularly limited thereto.

For example, the synthetic resin layer may include at least one of acrylate-based resin, methacrylate-based resin, polyisoprene, vinyl-based resin, epoxy-based resin, urethane-based resin, cellulose-based resin, siloxane-based resin, polyamide-based resin, and/or perylene-based resin. Besides, the base layer may include a glass substrate, a metal substrate, an organic/inorganic composite substrate, or the like.

At least one inorganic layer is formed on an upper surface of the base layer 110. For example, the inorganic layer may include at least one of aluminum oxide, titanium oxide, silicon oxide, silicon oxynitride, zirconium oxide, and/or hafnium oxide. The inorganic layer may be formed of multiple layers. The multi-layered inorganic layers may constitute a barrier layer BRL and/or a buffer layer BFL, which will be described later. The barrier layer BRL and the buffer layer BFL may be disposed selectively.

The barrier layer BRL may prevent foreign objects from being entered from the outside. The barrier layer BRL may include, for example, a silicon oxide layer and a silicon nitride layer. Each of the silicon oxide layer and the silicon nitride layer may include a plurality of layers, and the plurality of silicon oxide layers and the silicon nitride layers may be alternately stacked on each other.

The buffer layer BFL may be disposed on the barrier layer BRL. The buffer layer BFL may increase a bonding force between the base layer BL and the semiconductor pattern and/or the conductive pattern. The buffer layer BFL may include, for example, a silicon oxide layer and a silicon nitride layer. The silicon oxide layer and the silicon nitride layer may be alternately stacked on each other.

The semiconductor pattern is disposed on the buffer layer BFL. For example, the semiconductor pattern may be directly disposed on the buffer layer BFL. Hereinafter, the semiconductor pattern that is disposed on the buffer layer BFL may be a first semiconductor pattern. The first semiconductor pattern may include, for example, a silicon semiconductor. The first semiconductor pattern may include, for example, polysilicon. However, an embodiment of the present invention is not limited thereto. For example, the first semiconductor pattern may include amorphous silicon.

The first semiconductor pattern has electrical characteristics that are different from one another depending on whether the first semiconductor pattern is doped or not. The first semiconductor pattern may include a doped area and an undoped area. The doped area may be doped with an N-type dopant or a P-type dopant. A P-type transistor may include a doped area that is doped with the P-type dopant, and an N-type transistor may include a doped area that is doped with the N-type dopant.

The doped area has a higher conductivity than the undoped area, and substantially operates as an electrode or signal line. The undoped area substantially corresponds to the active area (or a channel) of a transistor. In other words, a part of the first semiconductor pattern may be an active area of a transistor. Another part thereof may be a source or drain of the transistor. Another part thereof may be a connection signal line (or a connection electrode). FIG. 5 shows a first transistor T1 as an example of a first semiconductor pattern.

The first semiconductor pattern of the first transistor T1 may include a first electrode S1, a channel part A1, and a second electrode D1 of the first transistor T1. The first electrode S1 and the second electrode D1 of the first transistor T1 may extend in opposite directions from the channel part A1.

A portion of a connection signal line CSL formed from the semiconductor pattern is illustrated in FIG. 5.

A first insulating layer 10 is disposed on the buffer layer BFL. The first insulating layer 10 overlaps the plurality of pixels in common and covers the first semiconductor pattern. The first insulating layer 10 may be an inorganic layer and/or an organic layer, and may have a single layer or multi-layer structure. The first insulating layer 10 may include at least one of, for example, an aluminum oxide, a titanium oxide, a silicon oxide, a silicon oxynitride, a zirconium oxide, and/or a hafnium oxide. In an embodiment of the present invention, the first insulating layer 10 may be a silicon oxide layer having a single layer structure. Not only the first insulating layer 10 but also an insulating layer of the circuit layer 120, which is to be described later, may be an inorganic layer and/or an organic layer, and may have a single layer structure or a multi-layer structure. The inorganic layer may include at least one of the materials described above.

A third electrode G1 of the first transistor T1 is disposed on the first insulating layer 10. The third electrode G1 may be a portion of a metal pattern. The third electrode G1 of the first transistor T1 overlaps the channel part A1 of the first transistor T1. In a process of doping the first semiconductor pattern, the third electrode G1 of the first transistor T1 may serve as a mask.

A second insulating layer 20 covering the third electrode G1 is disposed on the first insulating layer 10. The second insulating layer 20 overlaps a plurality of pixels PX in common. The second insulating layer 20 may be an inorganic layer and/or an organic layer, and may have a single layer structure or a multi-layer structure. In an embodiment of the present invention, the second insulating layer 20 may be a silicon oxide layer having a single layer structure.

An upper electrode UE may be disposed on the second insulating layer 20. The upper electrode UE may overlap the third electrode G1. The upper electrode UE may be a portion of a metal pattern or a portion of a doped semiconductor pattern. A portion of the third electrode G1 and the upper electrode UE overlapping the portion of the third electrode G1 may form a capacitor. In an embodiment of the present invention, the upper electrode UE may be omitted.

In an embodiment of the present invention, the second insulating layer 20 may be replaced with an insulating pattern. For example, the insulating pattern may be formed from the second insulating layer 20. The upper electrode UE may be arranged on the insulating pattern. The upper electrode UE may serve as a mask for forming an insulating pattern from the second insulating layer 20.

A third insulating layer 30 covers the upper electrode UE and is disposed on the second insulating layer 20. In an embodiment of the present invention, the third insulating layer 30 may be a silicon oxide layer having a single layer structure. A semiconductor pattern is arranged on the third insulating layer 30. For example, the semiconductor pattern may be directly disposed on the third insulating layer 30. Hereinafter, the semiconductor pattern directly disposed on the third insulating layer 30 may be referred to as a second semiconductor pattern. The second semiconductor pattern may include, for example, metal oxide. The oxide semiconductor may include a crystalline or amorphous oxide semiconductor. For example, the oxide semiconductor may include oxides of metals (e.g., zinc (Zn), indium (In), gallium (Ga), tin (Sn), titanium (Ti), and the like) or a mixture of the metals (e.g., zinc (Zn), indium (In), gallium (Ga), tin (Sn), titanium (Ti), and the like) and oxides of the metals. The oxide semiconductors may include, for example, indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), zinc-tin oxide (ZTO), and the like.

The second semiconductor pattern may include a plurality of areas identified depending on whether the metal oxide is reduced. An area (hereinafter referred to as a “reduction area”) in which the metal oxide is reduced has higher conductivity than an area (hereinafter referred to as a “non-reduction area”) in which the metal oxide is not reduced. The reduction area substantially has a role of an electrode or signal line. The non-reduction area substantially corresponds to a channel part of a transistor. In other words, the portion of the second semiconductor pattern may be a channel part of a transistor, and another portion thereof may be a first electrode or a second electrode of the transistor. FIG. 5 shows a third transistor T3 as an example of a second semiconductor pattern.

The second semiconductor pattern of the third transistor T3 includes a first electrode S3, a channel part A3, and a second electrode D3. The first electrode S3 and the second electrode D3 include a metal reduced from a metal oxide semiconductor. The first electrode S3 and the second electrode D3 of the first transistor T3 may extend in opposite directions from the channel part A3. The first electrode S3 and the second electrode D3 may include a metal layer including the reduced metal.

A fourth insulating layer 40 covering the second semiconductor pattern is disposed on the third insulating layer 30. In an embodiment of the present invention, the fourth insulating layer 40 may be a silicon oxide layer having a single layer structure. A third electrode G3 of the third transistor T3 is disposed on the fourth insulating layer 40. The third electrode G3 may be a portion of a metal pattern. The third electrode G3 of the third transistor T3 overlaps the channel part A3 of the third transistor T3.

In an embodiment of the present invention, the fourth insulating layer 40 may be replaced with an insulating pattern. For example, the insulating pattern may be formed from the fourth insulating layer 40. The third electrode G3 of the third transistor T3 is disposed on the insulating pattern. In an embodiment of the present invention, the third electrode G3 may have the same shape as the insulating pattern in a plan view. In an embodiment of the present invention, for convenience of description, the one third electrode G3 is illustrated, but the third transistor T3 may include two third electrodes.

A fifth insulating layer 50 covering the third electrode G3 is disposed on the fourth insulating layer 40. In an embodiment of the present invention, the fifth insulating layer 50 may include a silicon oxide layer and a silicon nitride layer. The fifth insulating layer 50 may include a plurality of silicon oxide layers and a plurality of silicon nitride layers, which are alternately stacked on each other.

At least one insulating layer is further disposed on the fifth insulating layer 50. In an embodiment of the present invention, a sixth insulating layer 60 and a seventh insulating layer 70 may be disposed on the fifth insulating layer 50. Each of the sixth insulating layer 60 and the seventh insulating layer 70 may be organic layers, and may have a single layer or multi-layer structure. For example, each of the sixth insulating layer 60 and the seventh insulating layer 70 may be a polyimide-based resin layer having a single layer structure. However, the present invention is not limited thereto. For example, the sixth insulating layer 60 and the seventh insulating layer 70 may include at least one of acrylate-based resin, methacrylate-based resin, polyisoprene, vinyl-based resin, epoxy-based resin, urethane-based resin, cellulose-based resin, siloxane-based resin, polyamide-based resin, and perylene-based resin.

A first connection electrode CNE10 may be disposed on the fifth insulating layer 50. The first connection electrode CNE10 may be connected to the connection signal line CSL through a first contact hole CH1 that penetrates the first to fifth insulating layers 10 to 50. A second connection electrode CNE20 may be connected to the first connection electrode CNE10 through a contact hole CH-60 that penetrates the sixth insulating layer 60. In an embodiment of the present invention, at least one of the fifth insulating layer 50 and the sixth insulating layer 60 may be omitted.

The light emitting element layer 130 includes the light emitting element ED and a pixel defining layer PDL. An anode AE of the light emitting element ED is disposed on the seventh insulating layer 70. The anode AE of the light emitting element ED may be connected to the second connection electrode CNE20 through a contact hole CH-70 that penetrates the seventh insulating layer 70. The light emitting element ED may include an organic light emitting diode.

An opening OP of the pixel defining layer PDL exposes at least part of the anode AE of the light emitting element ED. The opening OP of the pixel defining layer PDL may define an emission area PXA. For example, the plurality of pixels may be disposed on a plane of the display layer 100 based on a specific rule. An area in which the plurality of pixels PX are disposed may be a pixel area. One pixel area may include the emission area PXA and a non-emission area NPXA that is adjacent to the emission area PXA. The non-emission area NPXA may surround the emission area PXA.

A hole control layer HCL may be disposed in common in the emission area PXA and the non-emission area NPXA; however, the present invention is not limited thereto. A common layer such as the hole control layer HCL may be formed in common in the plurality of pixels PX. The hole control layer HCL may include a hole transport layer and a hole injection layer.

A light emitting layer EML is disposed on the hole control layer HCL. The light emitting layer EML may be disposed in an area corresponding to the opening OP. The light emitting layer EML may be separately formed in each of the plurality of pixels PX.

In an embodiment of the present invention, the patterned light emitting layer EML is illustrated. However, the light emitting layer EML may be commonly disposed in the plurality of pixels PX. At this time, the light emitting layer EML may generate white light or blue light. In addition, the light emitting layer EML may have a multi-layer structure.

An electron control layer ECL is disposed on the light emitting layer EML. The electron control layer ECL may include an electron transport layer and an electron injection layer. A cathode CE of the light emitting element ED is disposed on the electron control layer ECL. The electron control layer ECL and the cathode CE are disposed in common in the plurality of pixels PX.

The encapsulation layer 140 is disposed on the cathode CE. The encapsulation layer 140 may cover the plurality of pixels. In an embodiment of the present invention, the encapsulation layer 140 directly covers the cathode CE. In an embodiment of the present invention, the display layer 100 may further include a capping layer that directly covers the cathode CE. In an embodiment of the present invention, the stacked structure of the light emitting element ED may have a vertically inverted structure in the structure shown in FIG. 5.

The encapsulation layer 140 may be disposed on the light emitting element layer 130. The encapsulation layer 140 may include an inorganic layer, an organic layer, and an inorganic layer sequentially stacked on each other, and layers constituting the encapsulation layer 140 are not limited thereto.

The inorganic layers may protect the light emitting element layer 130 from moisture and oxygen, and the organic layer may protect the light emitting element layer 130 from a foreign material such as dust particles. The inorganic layers may include, for example, a silicon nitride layer, a silicon oxynitride layer, a silicon oxide layer, a titanium oxide layer, an aluminum oxide layer, or the like. The organic layer may include, for example, an acrylate-based organic layer, but the present invention is not limited thereto.

The sensor layer 200 may include a base layer 201, a first conductive layer 202, a sensing insulating layer 203, a second conductive layer 204, and a cover insulating layer 205.

For example, the base layer 201 may be an inorganic layer including at least one of silicon nitride, silicon oxynitride, and/or silicon oxide. In addition, the base layer 201 may be an organic layer including an epoxy resin, an acrylate resin, or an imide-based resin. The base layer 201 may have a single layer structure or may have a multi-layer structure stacked in the third direction DR3.

Each of the first conductive layer 202 and the second conductive layer 204 may have a single layer structure or may have a multi-layer structure in which layers are stacked in the third direction DR3.

A conductive layer of a single layer structure may include a metal layer or a transparent conductive layer. The metal layer may include, for example, molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), indium zinc tin oxide (IZTO), or the like. Besides, the transparent conductive layer may include a conductive polymer such as PEDOT, a metal nano wire, graphene, and the like.

A conductive layer of the multi-layer structure may include metal layers. For example, the metal layers may have a three-layer structure of titanium/aluminum/titanium. The conductive layer of the multi-layer structure may include at least one metal layer and at least one transparent conductive layer.

At least one of the detection insulating layer 203 and the cover insulating layer 205 may include an inorganic film. For example, the inorganic film may include at least one of aluminum oxide, titanium oxide, silicon oxide, silicon nitride, silicon oxynitride, zirconium oxide, and/or hafnium oxide.

At least one of the detection insulating layer 203 and the cover insulating layer 205 may include an organic film. The organic film may include, for example, at least one of acrylate-based resin, methacrylate-based resin, polyisoprene, vinyl-based resin, epoxy-based resin, urethane-based resin, cellulose-based resin, siloxane-based resin, polyimide-based resin, polyamide-based resin, and/or perylene-based resin.

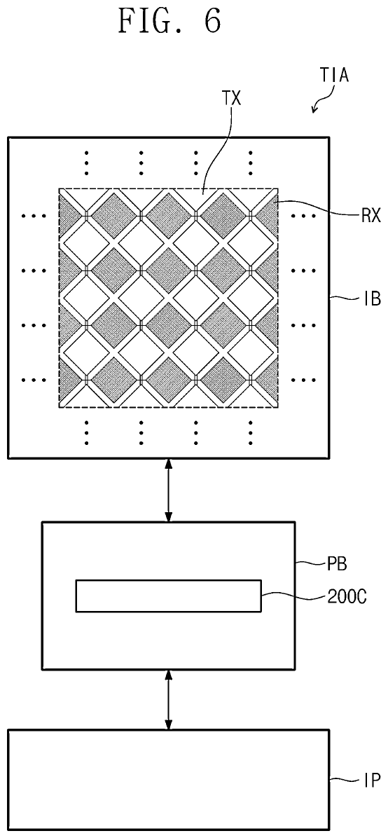

FIG. 6 is a block diagram showing a touch IC inspection device, according to an embodiment of the present invention.

Referring to FIG. 6, a touch IC inspection device TIA may inspect the touch IC 200C for defects and performance degradation.

The touch IC inspection device TIA may include an inspection board IB and an inspection part IP.

The inspection board IB may be electrically connected to the touch IC 200C. For example, the inspection board IB may be connected to the circuit board PB through a connector to be electrically connected to the touch IC 200C. The inspection board IB may be driven in response to signals that are provided from the touch IC 200C.

The inspection board IB may include a plurality of first electrodes TX and a plurality of second electrodes RX. This will be described later.

The inspection part IP may be electrically connected to the inspection board IB through the circuit board PB. For example, the inspection part IP may be connected to the circuit board PB through a connector, etc. For example, the inspection part IP may be an inspection circuit. For example, the inspection part IP may include a memory and a processor.

The inspection part IP may drive the inspection board IB by using the touch IC 200C. The inspection part IP may receive inspection results, which are obtained by driving the inspection board IB, from the touch IC 200C. The inspection part IP may inspect defects in the touch IC 200C based on the inspection results.

The touch IC 200C may be implemented as an integrated circuit (IC), and may be mounted on the separate circuit board PB in a chip on film (COF) method to be electrically connected to the sensor layer 200.

According to an embodiment of the present invention, the plurality of circuit boards PB, on each of which the touch IC 200C is mounted, may be provided. In other words, the touch IC inspection device TIA may inspect each of the plurality of touch ICs 200C.

According to an embodiment of the present invention, the touch IC inspection device TIA may inspect the performance of each of the plurality of touch ICs 200C under the same condition. The touch IC 200C with defects may be easily screened by comparing the inspection results of the plurality of touch ICs 200C. Afterward, the touch IC 200C with defects may be controlled to operate normally through performance tuning. Accordingly, the touch IC inspection device TIA having increased inspection reliability may be provided.

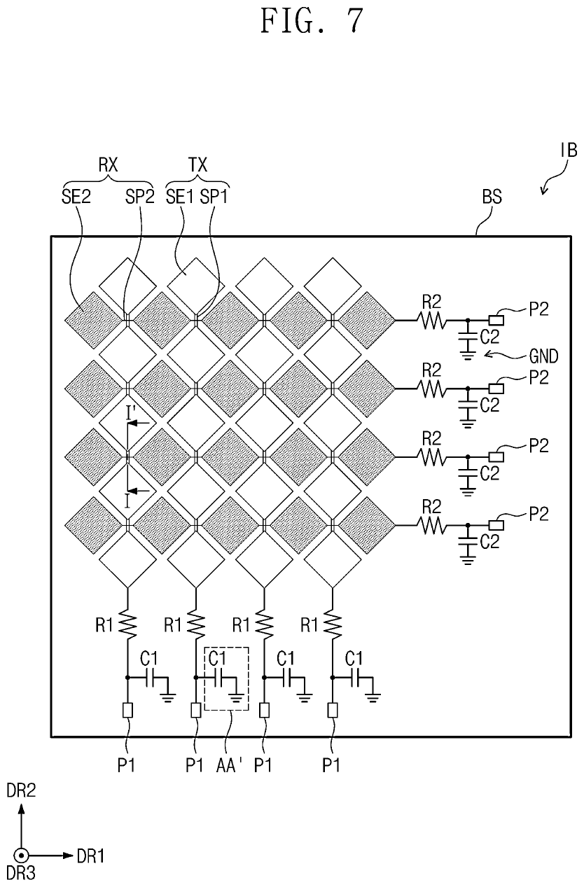

FIG. 7 is a conceptual diagram showing an inspection board, according to an embodiment of the present invention.

Referring to FIGS. 6 and 7, the inspection board IB may include a base layer BS, the plurality of first electrodes TX, the plurality of second electrodes RX, a first resistor R1, a first capacitor C1, a second resistor R2, and a second capacitor C2.

The base layer BS may have a plane defined by the first direction DR1 and the second direction DR2 that intersects the first direction DR1. The base layer BS may include substantially the same material as the base layer 201 (see FIG. 5). The plurality of first electrodes TX, the plurality of second electrodes RX, the first resistor R1, the first capacitor C1, the second resistor R2, and the second capacitor C2 may be disposed on the base layer BS.

Each of the plurality of first electrodes TX may extend in the second direction DR2. The plurality of first electrodes TX may be spaced apart from each other in the first direction DR1. The plurality of first electrodes TX may include conductive materials. For example, the plurality of first electrodes TX may include the same material as the first conductive layer 202 (see FIG. 5) and the second conductive layer 204 (see FIG. 5). The plurality of first electrodes TX may have a diamond pattern.

Each of the plurality of first electrodes TX may include a sensing pattern SE1 and a bridge pattern SP1. The two sensing patterns SE1 adjacent to each other in the second direction DR2 may be electrically connected to each other by the two bridge patterns SP1, but are not particularly limited thereto. The sensing pattern SE1 and the bridge pattern SP1 may be disposed on different layers from each other.

Each of the plurality of second electrodes RX may extend in the first direction DR1. The plurality of second electrodes RX may be spaced apart from each other in the second direction DR2. The plurality of second electrodes RX may include conductive materials. For example, the plurality of second electrodes RX may include the same material as the first conductive layer 202 (see FIG. 5) and the second conductive layer 204 (see FIG. 5). The plurality of second electrodes RX may have a diamond pattern.

Each of the plurality of second electrodes RX may include a first portion SE2 and a second portion SP2. The two bridge patterns SP1 may intersect with the second portion SP2 in an insulation scheme. The first portion SE2 and the second portion SP2 may be integrated with each other, and may be disposed on the same layer as each other.

The numbers of first electrodes TX may be the same as the number of second electrodes RX. For example, the plurality of first electrodes TX may have 50 electrodes, and the plurality of second electrodes RX may have 50 electrodes. For this reason, when viewed from above a plane, the plurality of first electrodes TX and the plurality of second electrodes RX may have a square shape.

According to an embodiment of the present invention, the inspection part IP of the touch IC inspection device TIA may drive the inspection board IB by electrically connecting at least part of the plurality of first electrodes TX and the plurality of second electrodes RX. The inspection board IB may correspond to various models by being connected to the appropriate number of electrodes among the plurality of first electrodes TX and the plurality of second electrodes RX depending on the shape of the display layer 100 (see FIG. 2) and the sensor layer 200 (see FIG. 2). For example, when the touch IC 200C is used for a watch, the circuit board PB may be electrically connected to the ‘n’ first electrodes TX (‘n’ is a positive integer) and the ‘m’ second electrodes RX (‘m’ is a positive integer), which have a size corresponding to the watch of the inspection board IB. When the touch IC 200C is used for a mobile device, the circuit board PB may be electrically connected to the ‘k’ first electrodes TX (‘k’ is a positive integer) and the ‘1’ second electrodes RX (‘1’ is a positive integer), which have a size corresponding to the mobile device of the inspection board IB. In this case, ‘n’ may be smaller than ‘k’, and ‘m’ may be smaller than ‘l’. The inspection board IB of the touch IC inspection device TIA may easily inspect the touch IC 200C by corresponding to various models. Accordingly, the touch IC inspection device TIA having increased inspection reliability may be provided.

The first resistor R1 may be electrically connected to one end of each of the plurality of first electrodes TX. The first resistor R1 may include a variable resistor. One end of the first resistor R1 may be connected to one end of each of the plurality of first electrodes TX, and the other end of the first resistor R1 may be connected to the first capacitor C1 and a first terminal P1.

The first capacitor C1 may be connected between the first resistor R1 and a ground electrode GND. The first capacitor C1 may be a variable capacitor.

The second resistor R2 may be electrically connected to one end of each of the plurality of second electrodes RX. The second resistor R2 may include a variable resistor. One end of the second resistor R2 may be connected to one end of each of the plurality of second electrodes RX, and the other end of the second resistor R2 may be connected to the second capacitor C2 and a second terminal P2.

The second capacitor C2 may be connected between the second resistor R2 and the ground electrode GND. The second capacitor C2 may be a variable capacitor.

The inspection board IB may be electrically connected to the circuit board PB through the first terminal P1 and a second terminal P2. In this case, the inspection board IB may have substantially the same function as the sensor layer 200. The touch IC 200C may easily drive the inspection board IB, and the inspection part IP may receive inspection results through the inspection board IB.

According to an embodiment of the present invention, the inspection board IB may adjust an element value of each of the first resistor R1, the first capacitor C1, the second resistor R2, and the second capacitor C2 to correspond to the sensor layer 200 (see FIG. 2) that is included in various product groups. When the touch IC 200C is inspected, a step of manufacturing the sensor layer 200 (see FIG. 2) may be omitted. When the touch ICs 200C in various product groups are inspected, the touch ICs 200C may be inspected by using one inspection board IB. As a result, inspection costs may be reduced and an inspection process may be shortened. Accordingly, the touch IC inspection device TIA having increased inspection reliability may be provided.

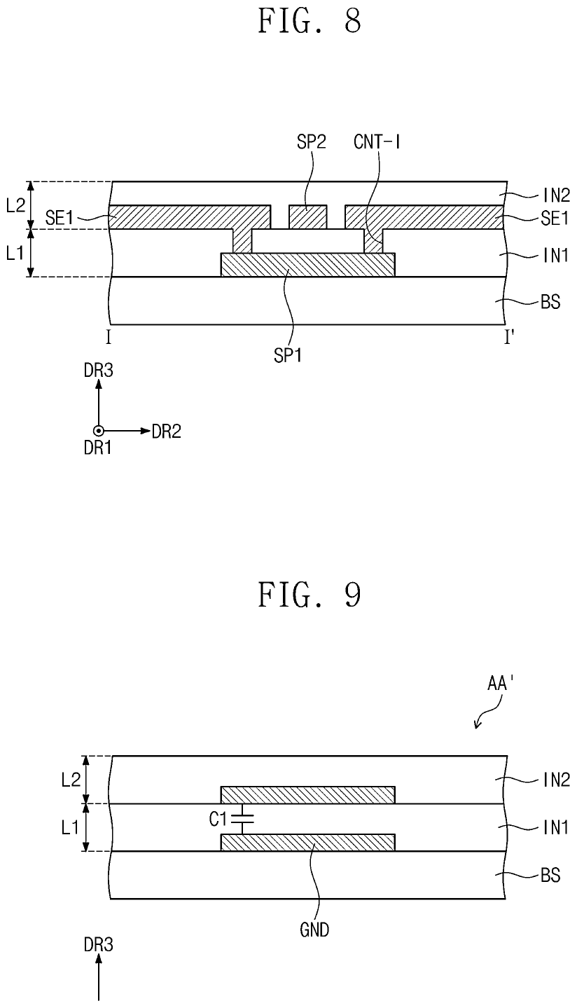

FIG. 8 is a cross-sectional view of an inspection board taken along I-I′ of FIG. 7, according to an embodiment of the present invention.

Referring to FIGS. 7 and 8, the bridge pattern SP1 may be disposed on the base layer BS.

A first insulating layer IN1 may cover the base layer BS and the bridge pattern SP1. The first insulating layer IN1 may include an insulating material. For example, the first insulating layer IN1 may include the same material as the sensing insulating layer 203 (see FIG. 5).

The bridge pattern SP1 and the first insulating layer IN1 may form a first layer L1.

The sensing pattern SE1, the first portion SE2, and the second portion SP2 may be disposed on the first insulating layer IN1. The sensing pattern SE1, the first portion SE2, and the second portion SP2 may be disposed on the same layer as each other. For example, a part of each of the plurality of first electrodes TX and the plurality of second electrodes RX may be disposed on the same layer as each other.

A second insulating layer IN2 may cover the first insulating layer IN1, the sensing pattern SE1, the first portion SE2, and the second portion SP2. The second insulating layer IN2 may include an insulating material. For example, the second insulating layer IN2 may include the same material as the cover insulating layer 205 (see FIG. 5).

The sensing pattern SE1 may be connected to the bridge pattern SP1 through a contact hole CNT-I that penetrates the first insulating layer IN1.

The second insulating layer IN2, the sensing pattern SE1, the first portion SE2, and the second portion SP2 may form a second layer L2.

The inspection board IB may have a bottom bridge structure. However, this is an example, and the stacked structure of the inspection board IB according to an embodiment of the present invention is not limited thereto. For example, the inspection board IB may have a top bridge structure in which locations of the first layer L1 and the second layer L2 are switched to each other.

FIG. 9 is a cross-sectional view of an inspection board that is obtained by cutting a portion corresponding to area AA′ of FIG. 7, according to an embodiment of the present invention. In the description of FIG. 9, the same reference numerals are assigned to the same components described with reference to FIG. 8, and thus, the descriptions thereof are omitted or briefly discussed to avoid redundancy.

Referring to FIGS. 7 and 9, the ground electrode GND may be disposed on the base layer BS. The ground electrode GND may be disposed on the same layer as the bridge pattern SP1. For example, the ground electrode GND may be disposed on the same layer as at least some of the parts of each of the plurality of first electrodes TX.

The first insulating layer IN1 may cover the ground electrode GND. The ground electrode GND may be referred to as a “first electrode of the first capacitor C1”.

A second electrode of the first capacitor C1 may be disposed on the first insulating layer IN1.

The second insulating layer IN2 may cover the second electrode of the first capacitor C1 and be disposed on the first insulating layer IN1.

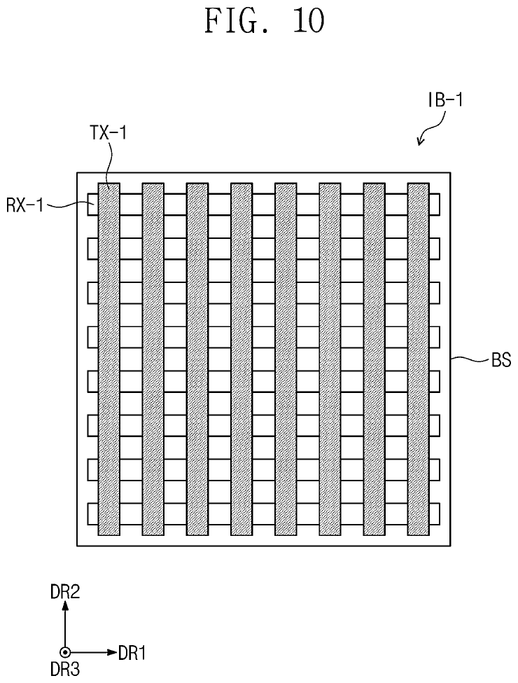

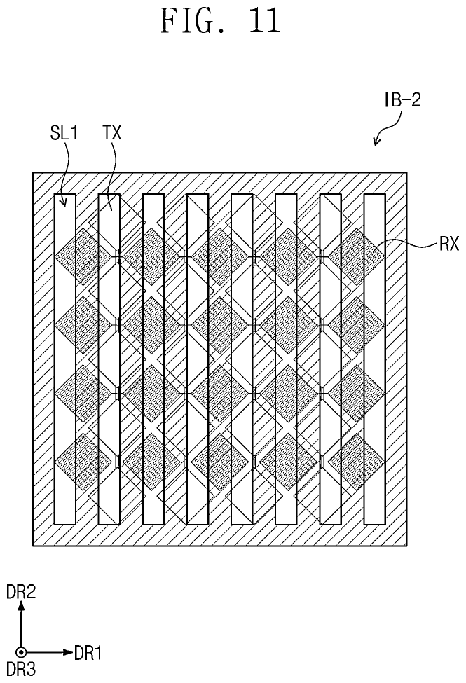

FIG. 10 is a plan view illustrating an inspection board, according to an embodiment of the present invention.

Referring to FIG. 10, an inspection board IB-1 may include the base layer BS, a plurality of first electrodes TX-1, and a plurality of second electrodes RX-1. However, this is an example, and the inspection board IB-1 according to an embodiment of the present invention may further include a plurality of resistors and a plurality of capacitors, or may include a plurality of ground layers.

Each of the plurality of first electrodes TX-1 may extend in the second direction DR2. The plurality of first electrodes TX-1 may be spaced apart from each other in the first direction DR1. The plurality of first electrodes TX-1 may have a bar pattern. For example, each of the plurality of first electrodes TX-1 may have a rectangular shape.

Each of the plurality of second electrodes RX-1 may extend in the first direction DR1. The plurality of second electrodes RX-1 may be spaced apart from each other in the second direction DR2. The plurality of second electrodes RX-1 may have a bar pattern. For example, each of the plurality of second electrodes RX-1 may have a rectangular shape.

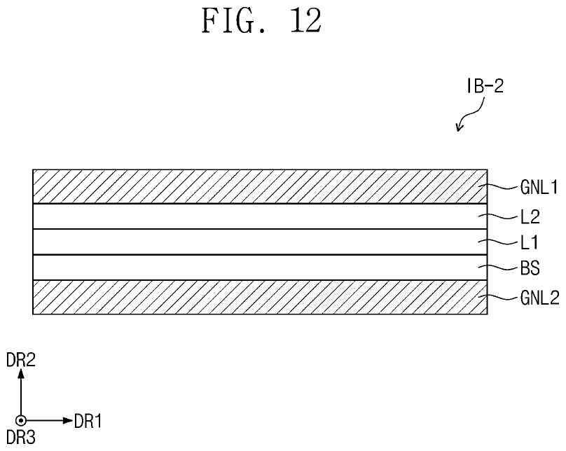

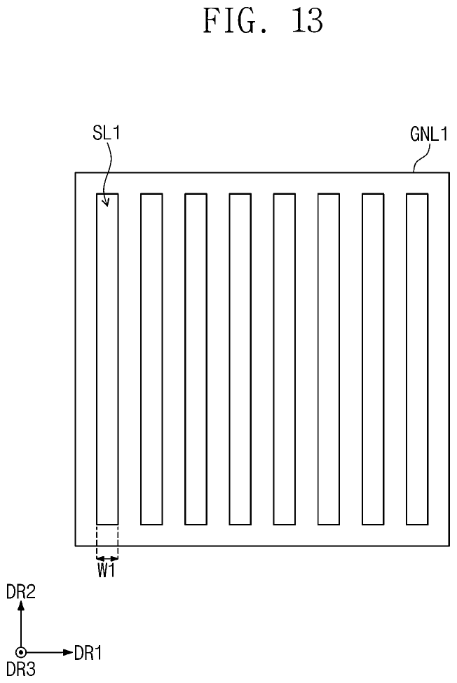

FIG. 11 is a plan view illustrating an inspection board, according to an embodiment of the present invention. FIG. 12 is a cross-sectional view illustrating an inspection board, according to an embodiment of the present invention. In the description of FIGS. 11 and 12, the same reference numerals are assigned to the same components that are described with reference to FIGS. 7 and 8, and thus, the descriptions thereof are omitted or briefly discussed to avoid redundancy.

Referring to FIGS. 11 and 12, an inspection board IB-2 may include a first ground layer GNL1, the second layer L2, which is disposed under the first ground layer GNL1, the first layer L1, which is disposed under the second layer L2, the base layer BS, which is disposed under the first layer L1, and a second ground layer GNL2, which is disposed under the base layer BS.

The first layer L1 and the second layer L2 may include the plurality of first electrodes TX and the plurality of second electrodes RX.

The first ground layer GNL1 may be disposed on the plurality of first electrodes TX and the plurality of second electrodes RX. A plurality of first slits SL1, each of which extends in the second direction DR2 and which are spaced apart from each other in the first direction DR1, may be defined on the first ground layer GNL1. For example, the plurality of first slits SL1 may be formed in the first ground layer GNL1. The first ground layer GNL1 may include conductive materials.

From a plan view, the plurality of first slits SL1 may overlap the plurality of first electrodes TX and the plurality of second electrodes RX.

The second ground layer GNL2 may be disposed under the plurality of first electrodes TX and the plurality of second electrodes RX. The second ground layer GNL2 may include conductive materials. The second ground layer GNL2 according to an embodiment of the present invention may be omitted.

The first resistor R1 (see FIG. 7), the first capacitor C1 (see FIG. 7), the second resistor R2 (see FIG. 7), and the second capacitor C2 (see FIG. 7) may be omitted on the inspection board IB-2 according to an embodiment of the present invention.

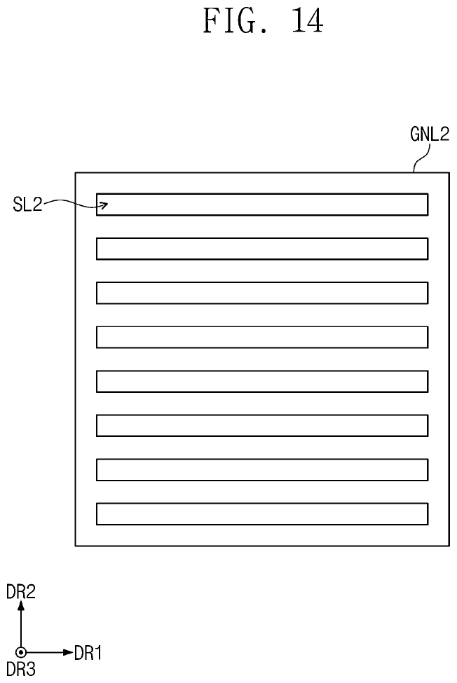

FIG. 13 is a plan view illustrating a first ground layer, according to an embodiment of the present invention. FIG. 14 is a plan view illustrating a second ground layer, according to an embodiment of the present invention.

Referring to FIGS. 13 and 14, the plurality of first slits SL1, each of which extends in the second direction DR2 and which are spaced apart from each other in the first direction DR1, may be formed in the first ground layer GNL1.

The self-capacitance of each of the plurality of first electrodes TX (see FIG. 11) may be controlled by a width W1 of each of the plurality of first slits SL1 in the first direction DR1.

A plurality of second slits SL2, each of which extends in the first direction DR1 and which are spaced apart from each other in the second direction DR2, may be formed in the second ground layer GNL2.

From a plan view, the plurality of second slits SL2 may overlap the plurality of first electrodes TX (see FIG. 11) and the plurality of second electrodes RX (see FIG. 11).

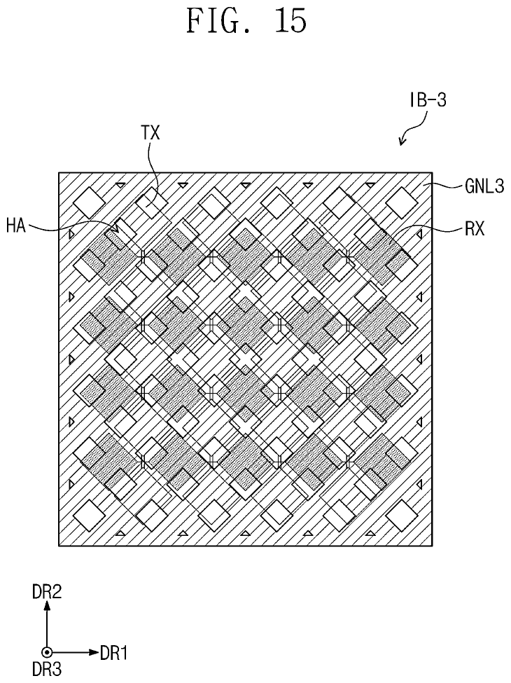

FIG. 15 is a plan view illustrating an inspection board, according to an embodiment of the present invention. In the description of FIG. 15, the same reference numerals are assigned to the same components described with reference to FIG. 7, and thus, the descriptions thereof are omitted or briefly discussed to avoid redundancy.

Referring to FIG. 15, an inspection board IB-3 may include the base layer BS (see FIG. 7), the plurality of first electrodes TX, the plurality of second electrodes RX, and a third ground layer GNL3.

The third ground layer GNL3 may be disposed on the plurality of first electrodes TX and the plurality of second electrodes RX.

A plurality of openings HA, each of which has a polygonal shape and which are arranged in the first direction DR1 and the second direction DR2, may be defined on the third ground layer GNL3. For example, the plurality of openings HA may be formed in the third ground layer GNL3.

From a plan view, the plurality of openings HA may overlap the plurality of first electrodes TX and the plurality of second electrodes RX. The self-capacitance of each of the plurality of first electrodes TX (see FIG. 11) may be controlled by an area of each of the plurality of openings HA.

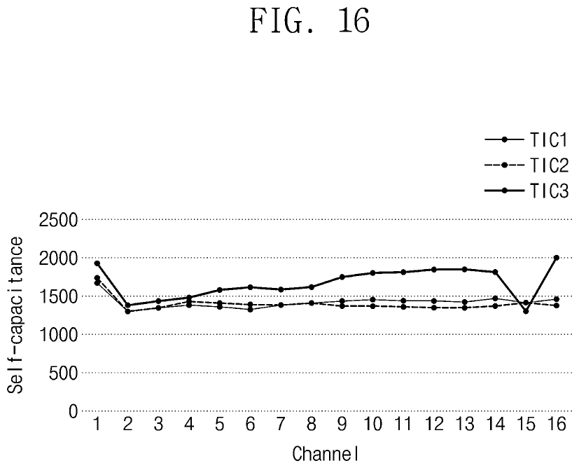

FIG. 16 illustrates an inspection result of measuring self-capacitance for each channel, according to an embodiment of the present invention.

In FIG. 16, a horizontal axis indicates channels of the plurality of first electrodes TX (see FIG. 7), and a vertical axis indicates self-capacitance of each of the plurality of first electrodes TX (see FIG. 7) measured in the inspection part IP (see FIG. 6).

Referring to FIGS. 6, 7, and 16, the touch IC inspection device TIA may inspect the performance of each of the three touch ICs 200C. The three touch ICs 200C may include a first touch IC, a second touch IC, and a third touch IC.

The touch IC inspection device TIA may be electrically connected to the circuit board PB, on which the first touch IC is mounted, and may inspect the performance of the first touch IC. In this case, the inspection part IP may receive a first inspection result TIC1. The first inspection result TIC1 may be provided as a graph that is obtained by measuring the self-capacitance of a channel of each of the plurality of first electrodes TX.

The touch IC inspection device TIA may be electrically connected to the circuit board PB, on which the second touch IC is mounted, and may inspect the performance of the second touch IC. In this case, the inspection part IP may receive a second inspection result TIC2. The second inspection result TIC2 may be provided as a graph that is obtained by measuring the self-capacitance of a channel of each of the plurality of first electrodes TX.

The first inspection result TIC1 and the second inspection result TIC2 according to an embodiment of the present invention may have substantially similar values to each other. In this way, the first touch IC and the second touch IC may be classified as good products (e.g., free of defects and having normal functionality).

The touch IC inspection device TIA may be electrically connected to the circuit board PB, on which the third touch IC is mounted, and may inspect the performance of the third touch IC. In this case, the inspection part IP may receive a third inspection result TIC3. The third inspection result TIC3 may be provided as a graph that is obtained by measuring the self-capacitance of a channel of each of the plurality of first electrodes TX.

The third inspection result TIC3 according to an embodiment of the present invention may have different values from values corresponding to the first inspection result TIC1 and the second inspection result TIC2. In this way, the third touch IC may be classified as a defective product. Afterward, the circuit board PB, on which the third touch IC that is separated from the touch IC inspection device TIA is mounted, may be corrected to have values similar to values corresponding to the first inspection result TIC1 and the second inspection result TIC2 through a step of tuning the performance. In this way, the circuit board PB on which the third touch IC is mounted may be controlled to operate normally.

According to an embodiment of the present invention, the touch IC inspection device TIA may inspect the performance of each of the plurality of touch ICs 200C under the same condition. The touch IC 200C with defects may be easily screened by comparing the inspection results of the plurality of touch ICs 200C. Afterward, the touch IC 200C with defects may be controlled to operate normally through performance tuning. Accordingly, the touch IC inspection device TIA having increased inspection reliability may be provided.

Although an embodiment of the present invention has been described for illustrative purposes, those skilled in the art will appreciate that various modifications, and substitutions are possible, without departing from the scope and spirit of the present invention. Accordingly, the technical scope of the present invention is not limited to the detailed description of this specification.

As described above, a touch IC inspection device is capable of inspecting the performance of each of a plurality of touch ICs under the same condition. A touch IC with defects may be easily screened by comparing test results of a plurality of touch ICs. Afterward, the touch IC with defects may be controlled to operate normally through performance tuning. Accordingly, a touch IC inspection device having increased inspection reliability may be provided.

While the present invention has been described with reference to embodiments thereof, it will be understood by those of ordinary skill in the art that various changes in form and details may be made thereto without departing from the spirit and scope of the present invention.

What is claimed is:

1. A touch integrated circuit (IC) inspection device comprising:
an inspection board electrically connected to a touch IC; and
an inspection circuit that receives an inspection result from the touch IC,
wherein the inspection board includes:
a plurality of first electrodes, each of which extends in a first direction and which are spaced apart from one another in a second direction that intersects the first direction; and
a plurality of second electrodes, each of which extends in the second direction and which are spaced apart from one another in the first direction, and
wherein a number of the plurality of first electrodes is a same as a number of the plurality of second electrodes.

2. The touch IC inspection device of claim 1, wherein each of the plurality of first electrodes and the plurality of second electrodes have a polygonal shape.

3. The touch IC inspection device of claim 1, wherein each of the plurality of first electrodes and the plurality of second electrodes have a rectangular shape.

4. The touch IC inspection device of claim 1, wherein a first part of each of the plurality of second electrodes and the plurality of first electrodes are disposed on a same layer.

5. The touch IC inspection device of claim 4, wherein the inspection board further includes:
a first resistor electrically connected to one end of each of the plurality of first electrodes; and
a first capacitor connected between the first resistor and a ground electrode.

6. The touch IC inspection device of claim 5, wherein the inspection board further includes:
a second resistor electrically connected to one end of each of the plurality of second electrodes; and
a second capacitor connected between the second resistor and the ground electrode.

7. The touch IC inspection device of claim 5, wherein the first resistor is a variable resistor, and
wherein the first capacitor is a variable capacitor.

8. The touch IC inspection device of claim 5, wherein the ground electrode is disposed on a same layer as a second part of each of the plurality of second electrodes.

9. The touch IC inspection device of claim 1, wherein the inspection board further includes:
a first ground layer disposed on the plurality of first electrodes and the plurality of second electrodes; and
a second ground layer disposed under the plurality of first electrodes and the plurality of second electrodes.

10. The touch IC inspection device of claim 9, wherein a plurality of first slits, each of which extends in the second direction and which are spaced apart from one another in the first direction, are disposed on the first ground layer, and
wherein the plurality of first slits overlap the plurality of first electrodes and the plurality of second electrodes.

11. The touch IC inspection device of claim 10, wherein self-capacitance of each of the plurality of first electrodes is controlled by a width, in a first direction, of each of the plurality of first slits.

12. The touch IC inspection device of claim 10, wherein a plurality of second slits, each of which extends in the first direction and which are spaced apart from one another in the second direction, are disposed on the second ground layer, and
wherein the plurality of second slits overlap the plurality of first electrodes and the plurality of second electrodes.

13. The touch IC inspection device of claim 9, wherein a plurality of openings, each of which has a polygonal shape and which are arranged in the first direction and the second direction, are disposed on the first ground layer, and
wherein the plurality of openings overlap the plurality of first electrodes and the plurality of second electrodes.

14. A touch integrated circuit (IC) inspection device comprising:
an inspection board electrically connected to a touch IC,
wherein the inspection board includes:
a plurality of first electrodes, each of which extends in a first direction and which are spaced apart from one another in a second direction that intersects the first direction;
a plurality of second electrodes, each of which extends in the second direction and which are spaced apart from one another in the first direction;
a first resistor electrically connected to one end of each of the plurality of first electrodes; and
a first capacitor connected between the first resistor and a ground electrode.

15. The touch IC inspection device of claim 14, wherein the first resistor is a variable resistor, and
wherein the first capacitor is a variable capacitor.

16. The touch IC inspection device of claim 14, wherein the inspection board further includes:
a second resistor electrically connected to one end of each of the plurality of second electrodes; and
a second capacitor connected between the second resistor and the ground electrode.

17. The touch IC inspection device of claim 14, wherein a first part of each of the plurality of second electrodes and the plurality of first electrodes are disposed on a same layer.

18. The touch IC inspection device of claim 17, wherein the ground electrode is disposed on a same layer as a second part of each of the plurality of second electrodes.

19. The touch IC inspection device of claim 14, wherein at least one of the plurality of first electrodes or the plurality of second electrodes have a diamond shape.

20. The touch IC inspection device of claim 14, wherein at least one of the plurality of first electrodes or the plurality of second electrodes have a rectangular shape.
